(19) United States
(12) Patent Application Publication
(10) Pub. No.: US 2024/0319753 A1
(43) Pub. Date: Sep. 26, 2024

(54) REGULATOR VOLTAGE DETECTION CIRCUIT AND SEMICONDUCTOR DEVICE

(71) Applicant: LAPIS Technology Co., Ltd., Yokohama (JP)

(72) Inventor: Takayoshi Fujino, Yokohama (JP)

(21) Appl. No.: 18/609,974

(22) Filed: Mar. 19, 2024

(30) Foreign Application Priority Data
Mar. 24, 2023 (JP) 2023-047928

(51) Int. Cl. G05F 1/565; G05F 1/46; G05F 1/575

(52) U.S. Cl. CPC G05F 1/565; G05F 1/468; G05F 1/575

(57) ABSTRACT

Provided is a regulator voltage detection circuit that can suppress a circuit area and current consumption inside the semiconductor device. A regulator voltage detection circuit of the disclosure outputs a detection signal indicating a voltage change of a regulator voltage output from a regulator circuit based on a reference voltage. The regulator voltage detection circuit includes a load element and a comparator. The load element includes a first terminal and a second terminal. A current is supplied from a constant current circuit to the first terminal. The second terminal receives the regulator voltage. The comparator includes a first input terminal connected to the first terminal and a second input terminal receiving the reference voltage. The comparator outputs the detection signal.

### CROSS-REFERENCE TO RELATED APPLICATION

This application is based upon and claims the benefit of priority from the prior Japanese Patent Application No. 2023-047928 filed on Mar. 24, 2023, the entire contents of which are incorporated herein by reference.

### BACKGROUND

### 1. Technical Field

The disclosure relates to a regulator voltage detection circuit and a semiconductor device.

### 2. Description of the Related Art

JP-A-10-111323 discloses a technique of a power supply voltage detecting device that detects whether or not a regulator voltage, which is an output of a regulator circuit, is abnormal relative to a reference voltage, as a regulator voltage detection circuit.

However, the regulator voltage detection circuit and a semiconductor device that frequently use resistance voltage dividing circuits such as ladder resistors, as the power supply voltage detecting device disclosed in JP-A-10-111323, have problems of becoming more complicated and tending to increase a circuit area and current consumption inside the semiconductor device.

The disclosure has been made in consideration of the above-described points, and it is one example of an object of the disclosure to provide a regulator voltage detection circuit and a semiconductor device that can suppress a circuit area and current consumption inside the semiconductor device.

### SUMMARY

A regulator voltage detection circuit of the disclosure outputs a detection signal indicating a voltage change of a regulator voltage output from a regulator circuit based on a reference voltage. The regulator voltage detection circuit includes a load element and a comparator. The load element includes a first terminal and a second terminal. A current is supplied from a constant current circuit to the first terminal. The second terminal receives the regulator voltage. The comparator includes a first input terminal connected to the first terminal and a second input terminal receiving the reference voltage. The comparator outputs the detection signal.

A semiconductor device of the disclosure includes a regulator voltage detection circuit that outputs a detection signal indicating a voltage change of a regulator voltage output from a regulator circuit based on a reference voltage. The semiconductor device includes a load element and a comparator. The load element includes a first terminal and a second terminal. A current is supplied from a constant current circuit to the first terminal. The second terminal receives the regulator voltage. The comparator includes a first input terminal connected to the first terminal and a second input terminal receiving the reference voltage. The comparator outputs the detection signal.

### BRIEF DESCRIPTION OF THE DRAWINGS

FIG. 1 is a circuit diagram illustrating a regulator circuit and a voltage detection circuit of a regulator voltage of Experimental example;

FIG. 2 is a graph illustrating an output change of a drop detection signal UVLO when a regulator voltage VREG and a divided voltage Vtres in the voltage detection circuit of the regulator voltage change with time response;

FIG. 3 is a circuit diagram illustrating the regulator circuit and the voltage detection circuit of the regulator voltage of Experimental example; and

FIG. 4 is a circuit diagram illustrating a regulator voltage detection circuit according to an embodiment of the disclosure.

### DETAILED DESCRIPTION

With the disclosure, it is possible to obtain the effect of suppressing the circuit area and the current consumption in the semiconductor device of the regulator voltage detection circuit.

The following describes a regulator voltage detection circuit according to embodiments of the disclosure together with Experimental examples with reference to accompanied drawings. In the embodiments and Experimental examples, identical reference numerals are given to the components having substantially identical functions and configurations, and the repeated explanation will be omitted.

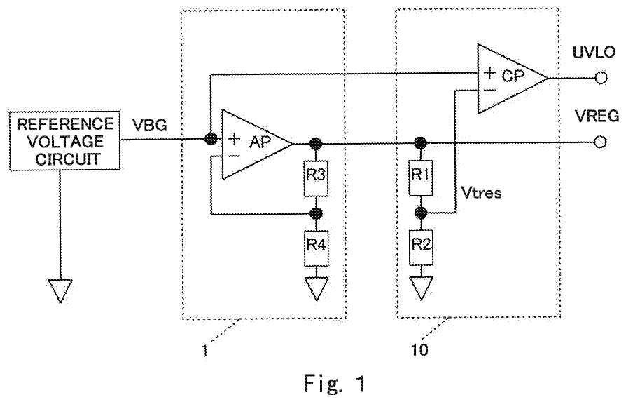

FIG. 1 is a circuit diagram illustrating a regulator circuit 1 and a voltage detection circuit 10 of Experimental example as one example of a voltage monitoring target.

The regulator circuit 1 illustrated in FIG. 1 is constituted of an error amplifier (an error amplifier) AP and feedback resistors R3, R4.

One end of the resistor R3 of ladder resistors R3, R4 of the feedback resistors is connected to the output of the error amplifier AP. The other end of the resistor R4 of the ladder resistors R3, R4 is grounded. A divided voltage that is divided by a predetermined ratio of the two series resistances of the ladder resistors R3, R4 is input into an inverting input terminal (−) of the error amplifier AP from an intermediate node.

A reference voltage VBG from a reference voltage circuit is input into a non-inverting input terminal (+) of the error amplifier AP. The error amplifier AP compares the reference voltage VBG and the divided voltage (a feedback voltage) from the ladder resistors, and outputs a regulator voltage VREG that is controlled so as to be a desired voltage.

The voltage detection circuit 10 of Experimental example illustrated in FIG. 1 is constituted of a comparator CP and ladder resistors R1, R2.

One end of the resistor R1 of the ladder resistors R1, R2 is connected to the output (the regulator voltage VREG) of the error amplifier AP of the regulator circuit 1. The other end of the resistor R2 of the ladder resistors R1, R2 is grounded. A divided voltage Vtres that is divided by a predetermined ratio of the two series resistances of the ladder resistors R1, R2 is input into an inverting input terminal (−) of the comparator CP from an intermediate node.

The reference voltage VBG from the reference voltage circuit is input into a non-inverting input terminal (+) of the comparator CP. Thus, the voltage detection circuit 10 configured to compare the reference voltage VBG and the divided voltage Vtres outputs a drop detection signal UVLO (a detection signal indicating a voltage change of the regulator voltage).

The divided voltage Vtres by the ladder resistors R1, R2 is expressed by the following formula.

$$Vtres = \frac{R 2}{R 1 + R 2} VREG$$

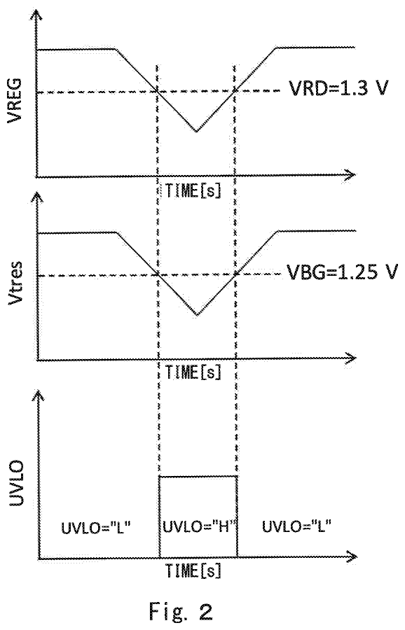

Here, an output of the drop detection signal UVLO when the regulator voltage VREG and the divided voltage Vtres change in the time response is indicated in FIG. 2. When the change in the divided voltage Vtres relative to the reference voltage VBG is Vtres>VBG, UVLO=L, and when the same change is Vtres<VBG, UVLO=H, and a drop is detected.

Here, a drop detection threshold voltage VRD that is an indicator of accuracy of the regulator voltage detection circuit will be considered. For example, assuming that the reference voltage VBG=1.25 V, and the drop detection threshold voltage VRD=1.3 V, a resistance ratio of the ladder resistors R1, R2 can be obtained from the following formula.

$$\frac{R 2}{R 1 + R 2} = \frac{VBG}{VRD} = \frac{1.25}{1.3}$$

As a result, the drop detection threshold voltage VRD can be set arbitrarily as long as it is within a range of the following formula.

$$0 < \frac{VBG}{VRD} \leq 1$$

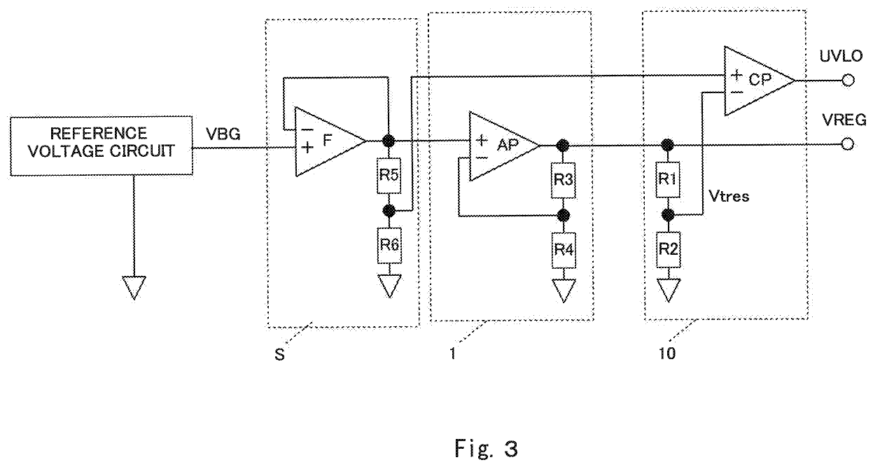

Thus, in the voltage detection circuit 10 of Experimental example, when the drop detection threshold voltage is VRD, and the reference voltage is VBG, it can only be set under a condition of 0<VBG/VRD≤1. For example, in order to set the drop detection threshold voltage VRD=1.2 V, it is required to dispose, for example, an auxiliary circuit S as illustrated in FIG. 3, between the reference voltage circuit and the voltage detection circuit 10, i.e., the regulator circuit 1. to provide a drop detection reference voltage. The auxiliary circuit S comprises a voltage follower buffer amplifier F, a non-inverting input terminal of which receives the reference voltage VBG and an inverting input terminal of which is connected to its output terminal, and ladder resistors R5, R6 that send a divided voltage from the output terminal of the buffer amplifier F to the voltage detection circuit 10. Accordingly, the drop detection threshold voltage VRD cannot be unconditionally set to a value lower than the reference voltage VBG, and a reference voltage for a drop detection is required, and thus, it is likely to increase a circuit area and current consumption inside a semiconductor device.

Thus, in order to be able to set the drop detection threshold voltage VRD in a wider range, in a regulator voltage detection circuit 100 formed in the semiconductor device according to this embodiment, the comparator CP that outputs the drop detection signal UVLO is configured to receive the reference voltage VBG, and a first voltage Vtres1 of a bias current I and a resistor R with the regulator voltage VREG as reference.

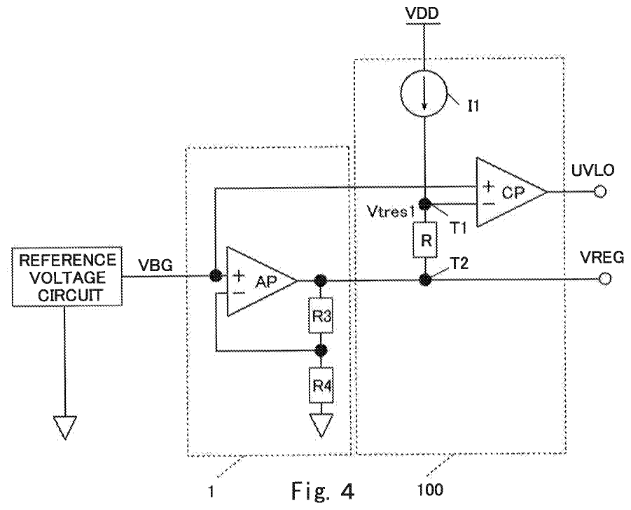

Namely, as illustrated in FIG. 4, the regulator voltage detection circuit 100 according to this embodiment is configured to have the resistor R (a load element) having a first terminal T1 to which a bias current I is supplied from a constant current circuit 11 and a second terminal T2 receiving the regulator voltage VREG, and the comparator CP that includes the inverting input terminal (−) (a first input terminal) connected to the first terminal T1 and the non-inverting input terminal (+) (a second input terminal) receiving the reference voltage VBG, and compares them to output the detection signal (the drop detection signal UVLO).

As illustrated in FIG. 4, in the comparator CP of the regulator voltage detection circuit 100, the reference voltage VBG is input into the non-inverting input terminal (+), and the first voltage Vtres1 at the first terminal T1 of the resistor R with the regulator voltage VREG as the reference is input into the inverting input terminal (−).

The first voltage Vtres1 by the first terminal T1 of the resistor R is expressed by the following formula.

$$Vtres 1 = VREG + I 1 * R$$

Here, in a case where the first voltage Vtres1 changes in the time response, when the change of the first voltage Vtres1 relative to the reference voltage VBG is Vtres1>VBG, UVLO=L, and when the change is Vtres1<VBG, UVLO=H, and the drop is detected.

Here, assuming that the reference voltage VBG=1.25 V, and the drop detection threshold voltage VRD=1.2 V, the voltage due to the resistor R and the bias current I can be obtained from the following formula.

$$I 1 * R = VBG - VREG = 1.25 - 1.2 = 0.05 [ V ]$$

Furthermore, assuming that the bias current I=100 nA, the resistor R is expressed by the following formula.

$$R = \frac{VBG - VREG}{I 1} = \frac{0.05}{100 nA} = 500 k Ω$$

This makes it possible to adjust the drop detection threshold voltage VRD even in the range indicated in the following formula.

VRD≤VBG

The regulator voltage detection circuit 100 according to this embodiment creates the first voltage Vtres1 with the regulator voltage VREG as the reference using the resistor R. This eliminates the need for the drop detection reference voltage (see FIG. 3), thus allowing reduction of the circuit area and the current consumption inside the semiconductor device.

In the regulator voltage detection circuit 100 according to this embodiment, since the first voltage Vtres1 is created with the regulator voltage VREG as the reference, the above-described reduction effect can be achieved when it is desired to set the drop detection threshold voltage VRD to a value lower than the reference voltage VBG.

Furthermore, the output level at the first terminal T1 of the resistor R in the regulator voltage detection circuit 100 according to this embodiment is small and does not substantially affect the output of the regulator voltage detection circuit 100, thus allowing stable power supply voltage monitoring.

What is claimed is:

1. A regulator voltage detection circuit that outputs a detection signal indicating a voltage change of a regulator voltage output from a regulator circuit based on a reference voltage, the regulator voltage detection circuit comprising:
a load element including a first terminal and a second terminal, a current being supplied from a constant current circuit to the first terminal, the second terminal receiving the regulator voltage; and
a comparator including a first input terminal connected to the first terminal and a second input terminal receiving the reference voltage, the comparator outputting the detection signal.

2. The regulator voltage detection circuit according to claim 1, wherein
the load element is a single resistor.

3. A semiconductor device including a regulator voltage detection circuit that outputs a detection signal indicating a voltage change of a regulator voltage output from a regulator circuit based on a reference voltage, the semiconductor device comprising:
a load element including a first terminal and a second terminal, a current being supplied from a constant current circuit to the first terminal, the second terminal receiving the regulator voltage; and
a comparator including a first input terminal connected to the first terminal and a second input terminal receiving the reference voltage, the comparator outputting the detection signal.
